(19) United States
(12) Patent Application Publication
(10) Pub. No.: US 2009/0094499 A1
(43) Pub. Date: Apr. 9, 2009

(54) REPRODUCTION APPARATUS AND REPRODUCTION METHOD

(75) Inventor: Yoshihiko DEOKA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Sony Corporation, Minato-ku (JP)

(21) Appl. No.: 12/205,997

(22) Filed: Sep. 8, 2008

(30) Foreign Application Priority Data
Oct. 3, 2007 (JP) 2007-259680

(51) Int. Cl. H03M 13/05; G06F 11/10

(52) U.S. Cl. 714/752; 714/E11.032

(57) ABSTRACT

Disclosed is a reproduction apparatus that reproduces signals of a plurality of channels including: a soft-decision portion that performs a soft decision on each bit of a block encoded with an LDPC code for each channel, as a bit string corresponding to a length of the LDPC code; a holding portion that holds a soft-decision result on the block basis for each channel; a decoding portion that inputs the soft-decision result on the block basis and obtains an estimated bit string by an iterative decoding; and a control portion that determines a priority order among channels for each of which a next block is subjected to the iterative decoding, based on an iteration count at an end of the iterative decoding for each channel, and controls the input of the soft-decision result so that the iterative decoding is performed for each channel in accordance with the priority order.

### CROSS REFERENCES TO RELATED APPLICATIONS

The present invention contains subject matter related to Japanese Patent Application JP 2007-259680 filed in the Japanese Patent Office on Oct. 3, 2007, the entire contents of which being incorporated herein by reference.

### BACKGROUND OF THE INVENTION

1. Field of the Invention

The present invention relates to a reproduction apparatus and a reproduction method for reproducing signals of a plurality of channels from a recording medium. In particular, the present invention relates to a reproduction apparatus and a reproduction method for performing reproduction by decoding an LDPC code.

2. Description of the Related Art

A low-density parity-check code (hereinafter, referred to as an LDPC code) is attracting lots of attention. It is becoming clear that similar to a turbo code or the like, the LDPC code can exhibit performance close to a Shannon limit as a code length thereof is increased. Further, the LDPC code has such a feature that a minimum distance is proportional to the code length, and thus a block error probability characteristic is favorable. In addition, there hardly occurs a so-called error floor phenomenon, which is observed as a decoding characteristic of the turbo code or the like. These are advantages of the LDPC code.

The greatest characteristic of the LDPC code is that a parity check matrix that defines the LDPC code is a sparse matrix. Herein, the sparse matrix refers to a matrix having a significantly small number of components of “1”. The encoding with the LDPC code is executed by generating a generator matrix G based on a check matrix H, and multiplying a binary information message by the generator matrix G, to thereby generate an encoding word. Specifically, an encoding apparatus that performs encoding with the LDPC code first calculates the generator matrix G that establishes an expression GH^{T}=0 in a relationship with a transposed matrix H^{T} of the check matrix H.

Meanwhile, as a method of decoding the LDPC code, a sum-product algorism is proposed. In the sum-product algorism, a calculation regarding a posterior probability is separated into a “variable node processing” and a “check node processing”, and they are repeatedly performed to thereby determine a bit string having high estimation accuracy. The posterior probability refers to a conditional probability regarding encoding words based on a premise that a reception signal is known. The sum-product algorism is obtained by approximating a bitwise maximum posterior probability decoding method, which is a method of calculating the posterior probability without omission. The sum-product algorism significantly increases efficiency of an approximate calculation by using the sparse matrix.

In the sum-product algorism, as an iteration count of an iterative decoding is increased, the estimation accuracy is improved and a code error can be corrected. In general, an upper limit is put on the iteration count. This is because, in the sum-product algorism, such a convergence that the increase in iteration count provides a bit string that meets a parity search condition is not ensured.

When the method of decoding the LDPC code with the sum-product algorism is used for a system required to conduct a real-time operation, for example, to reproduce data on an apparatus that performs record/reproduction with respect to a tape-like magnetic recording medium in real time, the upper limit of the iteration count should be set under further severe restriction. If a bit string that meets the parity search condition is not obtained even when the upper limit of the iteration count is exceeded, the iterative decoding is forcibly terminated as an error in the error correction.

In addition, Japanese Patent Application Laid-open No. 2007-6382 discloses a technique of determining, in an iterative decoding of an LDPC code, a maximum iteration count of each code block in order to determine an optimal iteration count in terms of processing efficiency and power consumption, based on an allowed time assignable to an iterative decoding for one frame, the number of code blocks in one frame, and each code block size.

### SUMMARY OF THE INVENTION

When the method of decoding the LDPC code with the sum-product algorism is used for data reproduction of a magnetic recording/reproducing apparatus for performing record/reproduction on multichannel with respect to a tape-like magnetic recording medium, an LDPC decoder for decoding the LDPC code is provided to each channel and the LDPC decoding on respective channels is performed in parallel, or the LDPC code is decoded on a channel one by one, that is, one LDPC decoder is used in a time-shared manner to perform a time-shared iterative decoding on each channel.

In consideration of a cost in preference to other issues, a structure in which the time-shared LDPC decoding is performed on the plurality of channels using one LDPC decoder in a time-shared manner is adopted. In this case, however, the following problem arises.

In the case where the time-shared LDPC decoding is performed on the plurality of (in this case, two) channels using one LDPC decoder in the time-shared manner, a large number of iterative processings is required to obtain a bit string that meets a parity search condition in the LDPC decoding on a former channel. Therefore, when the iterative processing is repeated the maximum number of times determined in a system or repeated the number of times close thereto, there is a fear that the LDPC decoding cannot be performed on the next channel or, even if possible, it cannot be performed sufficiently, with the result that the LDPC decoding may be forcibly terminated, which may lead to occurrence of an error in the error correction.

In view of the above, there is considered a method in which the number of times obtained by evenly dividing, by the number of channels, a maximum iteration count determined in the system is distributed and assigned to the LDPC decoding on each channel. In this method, however, the maximum iteration count assigned to the iterative processing for the LDPC decoding on each channel is limited to 1/(the number of channels), with the result that use efficiency of the maximum iteration count determined in the system is decreased and an error rate is increased.

In view of the above-mentioned circumstances, the present invention has been made to provide a reproduction apparatus and a reproduction method capable of optimizing assignment of a finite iteration count to each of the plurality of channels when the time-shared iterative decoding of the LDPC code on the channels is performed using one LDPC decoder, and lowering the error rate.

To address the above-mentioned problems, in an embodiment of the present invention, it is desirable to provide a reproduction apparatus configured to reproduce signals of a plurality of channels. The reproduction apparatus includes a soft-decision means, a holding means, a decoding means, and a control means. The soft-decision means performs a soft decision on each bit of a block for each of the plurality of channels, the block being encoded with an LDPC (low-density parity-check) code as a bit string corresponding to a length of the LDPC code. The holding means holds a soft-decision result on a block basis for each of the plurality of channels, the soft-decision result being obtained by the soft-decision means. The decoding means inputs the soft-decision result on the block basis and obtains an estimated bit string by an iterative decoding. The control means determines a priority order among channels on each of which a next block is subjected to the iterative decoding, based on an iteration count at an end of the iterative decoding on each of the plurality of channels, and controls the input of the soft-decision result from the holding means to the decoding means on the block basis for each of the plurality of channels so that the iterative decoding is performed for each of the plurality of channels in accordance with the priority order.

In the embodiment of the present invention, the control means determines the priority order among channels on each of which the next block is subjected to the iterative decoding, based on the iteration count at the end of the iterative decoding on each of the plurality of channels, and controls the input of the soft-decision result on the block basis for each of the plurality of channels so that the iterative decoding is performed for each of the plurality of channels in accordance with the priority order. As a result, assignment of a finite iteration count to the channels in a case where a time-shared iterative decoding is performed on the LDPC code on the plurality channels using one LDPC decoder can be optimized, and thus an error rate can be reduced.

In the reproduction apparatus in the embodiment of the present invention, the soft-decision means may obtain a log-likelihood ratio of a posterior probability on a bit basis as the soft-decision result.

In the reproduction apparatus in the embodiment of the present invention, the control means may determine the priority order among the plurality of channels so that a next block on a channel on which the iterative decoding is performed a smaller number of times than any other channels at the end of the iterative decoding is subjected to the iterative decoding in priority to the others. With this structure, a possibility that the iterative decoding on the first channel is ended by a smaller iteration count becomes high, and thus larger iteration count can be assigned to the iterative decoding on a next channel, which can reduce a block error occurrence probability. That is, the iteration count for the iterative decoding of the LDPC code increases as an SN ratio becomes smaller due to a poor-quality reproduction signal. The quality of the reproduction signal heavily depends on, for example, a characteristic of a recording head or a reproducing head, so the iteration count at the time of the iterative decoding on a specific channel is likely to be larger than that on another channel. Therefore, by performing the iterative decoding first on a channel whose preceding iteration count is smaller, a probability by which the larger finite iteration count can be assigned to iterative decoding on the next channel is increased.

In the reproduction apparatus according to the embodiment of the present invention, the decoding means sets an upper limit of the iteration count when the iterative decoding is performed on the plurality of channels. When real-time data reproduction is required, the upper limit of the iteration count is determined in consideration of a time pressure. In the present invention, by optimizing the assignment of the finite iteration count to the channels in the case where the upper limit of the iteration count is set as described above, the error rate can be reduced.

In the reproduction apparatus according to the embodiment of the present invention, the decoding means performs a calculation on the posterior probability in a variable node processing and a check node processing, and performs an iterative processing therebetween. This method is referred as a sum-product algorism with which a bit string having high estimation accuracy can be determined by repetitively performing an iterative processing. The posterior probability refers to a conditional probability regarding encoding words based on a premise that a reception signal is known. The sum-product algorism is obtained by approximating a bitwise maximum posterior probability decoding method, which is a method of calculating the posterior probability without omission. The sum-product algorism significantly increases efficiency of an approximate calculation by using the sparse matrix.

According to another embodiment of the present invention, there is provided a method of reproducing signals of a plurality of channels. The method comprises: performing a soft decision on each bit of a block for each of the plurality of channels, the block being encoded with an LDPC (low-density parity-check) code as a bit string corresponding to a length of the LDPC code; inputting the soft-decision result on the block basis and obtaining an estimated bit string by an iterative decoding; and determining a priority order among channels for each of which a next block is subjected to the iterative decoding, based on an iteration count at an end of the iterative decoding for each of the plurality of channels and performing control so that the iterative decoding is performed for each of the plurality of channels in accordance with the priority order.

According to the embodiment of the present invention, by determining the priority order among channels on each of which the next block is subjected to the iterative decoding based on the iteration count at the end of the iterative decoding on each of the plurality of channels, and performing control so that the iterative decoding is performed for each of the plurality of channels in accordance with the priority order, assignment of the finite iteration count to the channels in a case where the time-shared iterative decoding is performed on the LDPC code on the plurality channels using one LDPC decoder can be optimized, and thus an error rate can be reduced.

Another reproduction apparatus configured to reproduce signals of a plurality of channels includes a soft-decision portion, a holding portion, a decoding portion, and a control portion. The soft-decision portion performs a soft decision on each bit of a block for each of the plurality of channels, the block being encoded with an LDPC (low-density parity-check) code as a bit string corresponding to a length of the LDPC code. The holding portion holds a soft-decision result on a block basis for each of the plurality of channels, the soft-decision result being obtained by the soft-decision portion. The decoding portion inputs the soft-decision result on the block basis and obtains an estimated bit string by an iterative decoding. A control portion determines a priority order among the plurality of channels on each of which a next block is subjected to the iterative decoding, based on an iteration count at an end of the iterative decoding on each of the plurality of channels, and controls the input of the soft-decision result from the holding portion to the decoding portion on the block basis for each of the plurality of channels so that the iterative decoding is performed for each of the plurality of channels in accordance with the priority order.

According to the embodiments of the present invention, the assignment of the finite iteration count to the channels in the case where the time-shared iterative decoding is performed on the LDPC code on the plurality of channels using one LDPC decoder can be optimized, and thus the error rate can be reduced.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a block diagram showing a structure of a recording apparatus in a magnetic recording/reproducing apparatus according to an embodiment of the present invention;

FIG. 2 is a block diagram showing a structure of a reproducing apparatus in the magnetic recording/reproducing apparatus according to the embodiment of the present invention;

FIG. 3 is a diagram showing a structure of a recorded bit string of 1 block recorded on a recording medium by the recording apparatus shown in FIG. 1;

FIG. 4 is a diagram showing a node representation of a parity check matrix H of an LDPC code;

FIG. 5 is a flowchart of an iterative decoding of the LDPC code with an LDPC decoder;

FIG. 6 is a diagram showing a state where log-likelihood ratios (LLR) for each bit of 1 block are set to variable nodes;

FIG. 7 is a diagram showing a calculation of a message Bmn given from a variable node n to a check node m;

FIG. 8 is a diagram showing a calculation of a message Amn given from the check node m to the variable node n;

FIG. 9 is a flowchart regarding control on a buffer/selector controller in a case where a time-shared iterative decoding on two channels is performed using one LDPC decoder in a time-shared manner; and

FIG. 10 is a timing chart regarding control on an order of the iterative decoding between two channels.

### DESCRIPTION OF PREFERRED EMBODIMENT

Hereinafter, an embodiment of the present invention will be described with reference to the drawings.

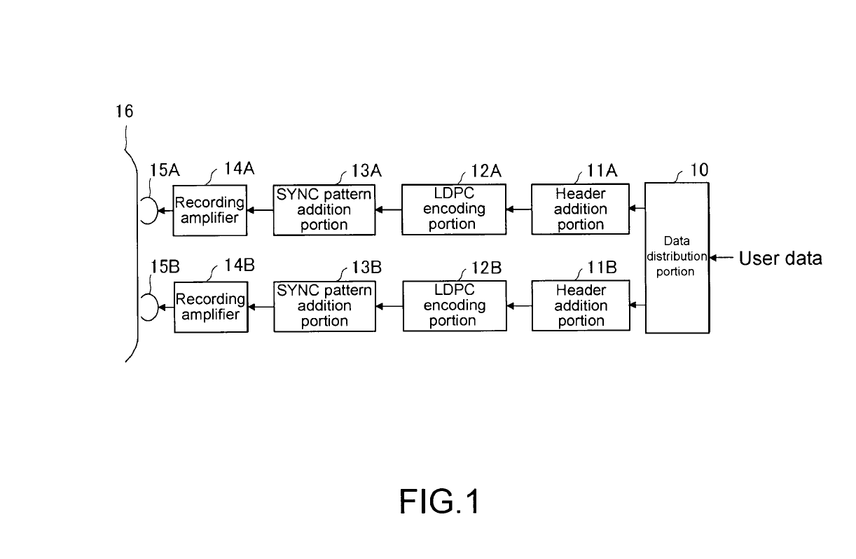

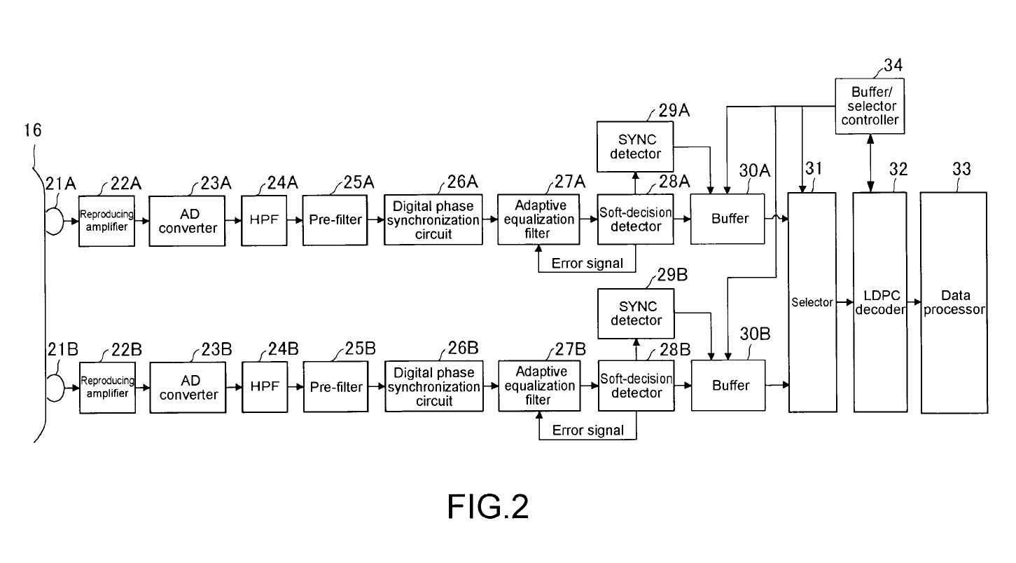

FIGS. 1 and 2 each show a structure of an embodiment in a case where a reproduction apparatus according to the embodiment of the present invention is applied to a magnetic recording/reproducing apparatus for performing record/reproduction with respect to a tape-like magnetic recording medium. FIG. 1 is a diagram showing a structure of a recording apparatus in the magnetic recording/reproducing apparatus. FIG. 2 is a diagram showing a structure of a reproducing apparatus in the magnetic recording/reproducing apparatus.

The magnetic recording/reproducing apparatus of this embodiment records signals of a plurality of channels on the tape-like magnetic recording medium with a plurality of recording heads, and reproduces the signals of the plurality of channels from the tape-like magnetic recording medium with a plurality of reproducing heads. In this embodiment, a description will be given on a case where the number of channels is two, but the number only have to be at least two in the present invention.

First, the structure of the recording apparatus will be described with reference to FIG. 1. As shown in FIG. 1, the recording apparatus includes a data distribution portion 10, header addition portions 11A and 11B, LDPC encoding portions 12A and 12B, SYNC pattern addition portions 13A and 13B, recording amplifiers 14A and 14B, and recording heads 15A and 15B. Herein, the header addition portions 11A and 11B, the LDPC encoding portions 12A and 12B, the SYNC pattern addition portions 13A and 13B, the recording amplifiers 14A and 14B, and the recording heads 15A and 15B are respectively provided to each channel.

The data distribution portion 10 divides user data into the number of channels and distributes the divided data to the header addition portions 11A and 11b on each channel.

The header addition portions 11A and 11B each add various additional information items as a header requisite for reproduction control to the user data divided for each channel.

The LDPC encoding portions 12A and 12B each perform LDPC encoding on the data to which the header is added and generate an LDPC encoding word.

The SYNC pattern addition portions 13A and 13B each add a SYNC pattern for detecting a block to a head of the encoding word generated by each of the LDPC encoding portions 12A and 12B.

The recording amplifiers 14A and 14B drive the recording heads 15A and 15B, respectively, based on a recording code string output from each of the SYNC pattern addition portions 13A and 13B. The recording heads 15A and 15B each record a signal on a tape-like magnetic recording medium 16.

Next, an operation of the recording apparatus of the magnetic recording/reproducing apparatus in this embodiment will be explained. First, user data is input in the data distribution portion 10, and divided into the number of channels to be distributed to the header addition portions 11A and 11B. A continuing operation for each channel is conducted as follows.

The header addition portions 11A and 11B each add, to the user data supplied from the data distribution portion 10, various additional information items as a header requisite for reproduction control of the user data. Subsequently, the LDPC encoding portions 12A and 12B each encode the data to which the header has been added so that the data is represented by a bit count corresponding to an LDPC code length N. The LDPC encoding is performed by calculating a generator matrix G that establishes GH^{T}=0 from a check matrix H that defines a parity code, and multiplying the data to which the header has been added by the generator matrix G, for example. Herein, the check matrix H that defines the parity code is characterized by being constituted of elements of “0” and “1” in M rows and N columns and being a sparse matrix. The sparse matrix refers to a matrix having a significantly small number of elements of “1”. The bit count obtained by encoding is the LDPC code length N. The bit string corresponding to the LDPC code length N is regarded as 1 block.

Next, the SYNC pattern is added to the head of the block by each of the SYNC pattern addition portions 13A and 13B, to thereby obtain a recording bit string of 1 block.

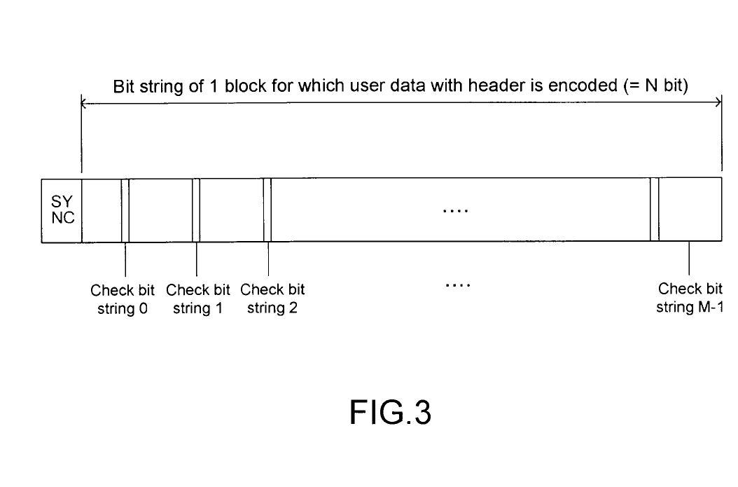

FIG. 3 shows a structure of the recording bit string of 1 block. As shown in FIG. 3, the SYNC pattern for block detection is added to the head of the recording bit string of 1 block. The SYNC pattern is followed by the encoding word as the bit string of 1 block obtained by encoding the user data to which the header has been added.

The encoding word is constituted of a message bit string of the user data to which the header has been added and the check bit string.

After that, the recording amplifiers 14A and 14B drive the recording heads 15A and 15B, respectively, based on the recording bit string, to thereby record signals on the tape-like magnetic recording medium 16.

Next, with reference to FIG. 2, the structure of the reproducing apparatus will be described. As shown in FIG. 2, the reproducing apparatus includes reproducing heads 21A and 21B, reproducing amplifiers 22A and 22B, AD converters 23A and 23B, HPFs (high pass filters) 24A and 24B, pre-filters 25A and 25B, digital phase synchronization circuits 26A and 26B, adaptive equalization filters 27A and 27B, soft-decision detectors 28A and 28B, SYNC detectors 29A and 29B, buffers 30A and 30B, a selector 31, an LDPC decoder 32, a data processor 33, and a buffer/selector controller 34. The reproducing heads 21A and 21B, the reproducing amplifiers 22A and 22B, the AD converters 23A and 23B, the HPFs (high pass filters) 24A and 24B, the pre-filters 25A and 25B, the digital phase synchronization circuits 26A and 26B, the adaptive equalization filters 27A and 27B, the soft-decision detectors 28A and 28B, the SYNC detectors 29A and 29B, and the buffers 30A and 30B are respectively provided to each channel. The selector 31, the LDPC decoder 32, the data processor 33, and the buffer/selector controller 34 are provided singly.

The reproducing heads 21A and 21B each read a signal recorded on the magnetic recording medium 16. The reproducing amplifiers 22A and 22B each amplify the output from each of the reproducing heads 21A and 21B to a level processable in subsequent circuits. The AD converters 23A and 23B each convert an analog reproduction signal output from each of the reproducing amplifiers 22A and 22B to a digital value. The HPFs 24A and 24B each remove low frequency components unnecessary in the subsequent processing from the output from the AD converters 23A and 23B. The pre-filters 25A and 25B each perform equalization processing on reproduction signals that have passed through the HPFs 24A and 24B for phase synchronization. The digital phase synchronization circuits 26A and 26B each generate phase-synchronized data series from the reproduction signals that have been asynchronously sampled by the AD converters 23A and 23B. The adaptive equalization filters 27A and 27B each update a tap coefficient thereof to an optimal value based on an error signal output from each of the soft-decision detectors 28A and 28B in the subsequent stage, and equalize the input signals to a predetermined target equalization characteristic.

As the soft-decision detectors 28A and 28B, a posterior probability detector is used, for example. The posterior probability detector calculates a posterior probability P0=P (x=0|Y=y), P1=P (x=1|Y=y) for each bit based on an input value y, and outputs a log-likelihood ratio (LLR) λ=log(P1/P0). Herein, x represents a recording bit, and takes either “0” or “1”, for example.

It is to be noted that the posterior probability detector may obtain the LLR from a plurality of input values including previous and next ones using a trellis diagram. The trellis diagram represents a code string generated in the course of change in state of the encoder according to an input bit string.

The SYNC detectors 29A and 29B each detect the SYNC pattern at the head of the block from the LLR determined by the soft-decision detectors 28A and 28B, and performs control so that the latest LLR of 1 block is held in the buffers 30A and 30B.

The buffers 30A and 30B each hold the LLR of 1 block for each channel. Write of the LLR on a block basis to the buffers 30A and 30B is controlled by the SYNC detectors 29A and 29B, and read thereof is controlled by the buffer/selector controller 34.

The selector 31 selects one of the buffers 30A and 30B for supplying the LLR on the block basis to the LDPC decoder 32 under the control of the buffer/selector controller 34.

The LDPC decoder 32 is a circuit for performing iterative decoding of the LDPC code with the LLR on the block basis input through the selector 31 as an input. The LDPC decoder 32 outputs, to the buffer/selector controller 34, the iteration count at the end of the iterative decoding for each channel.

The buffer/selector controller 34 includes a register for storing the iteration count at the end of the iterative decoding for each channel, which has been input by the LDPC decoder 32. Based on the iteration counts at the end of the iterative decoding for the channels, which are stored in the register, the buffer/selector controller 34 determines a priority order of the channels for which the iterative decodings are performed in the subsequent block. Then, the buffer/selector controller 34 reads data from the buffers 30A and 30B and controls the selector 31 so that the iterative decodings for the channels are successively performed in the order of priority.

The data processor 33 is a circuit for restoring data items for each channel based on an estimation encoding word obtained by the LDPC decoder 32 and connecting the data items to thereby restore the recording data.

Next, a detailed description will be given on iterative decoding of the LDPC code by the LDPC decoder 32. In this embodiment, the iterative decoding of the LDPC code is performed using a sum-product algorism. In the sum-product algorism, the calculation on the posterior probability is performed in two processings of a “variable node processing” and a “check node processing”. The processings are iteratively performed, to thereby determine a bit string having high estimation accuracy.

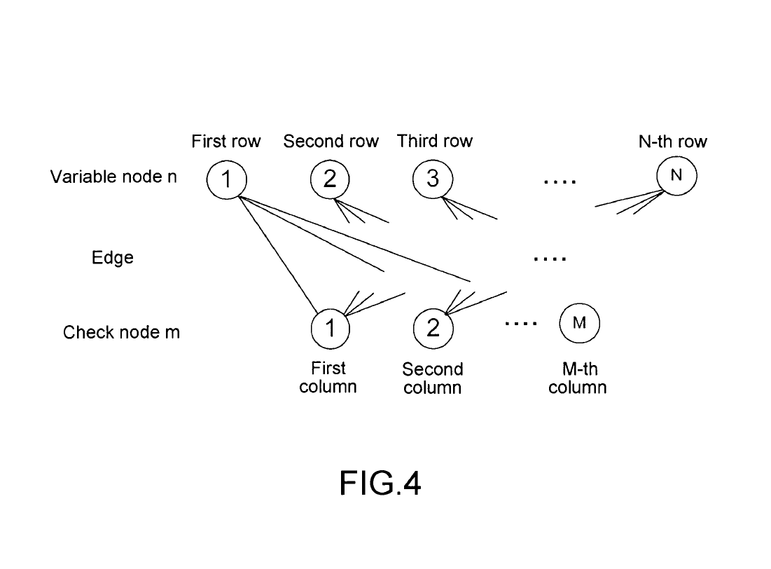

FIG. 4 is a diagram showing a node representation of the parity check matrix H of the LDPC code. The parity check matrix H (N rows and M columns) of the LDPC code is represented by N variable nodes, M check nodes, and edges. The edges connect a variable node n and a check node m when an element hmn in m-th row and n-th column of the parity check matrix H is “1”.

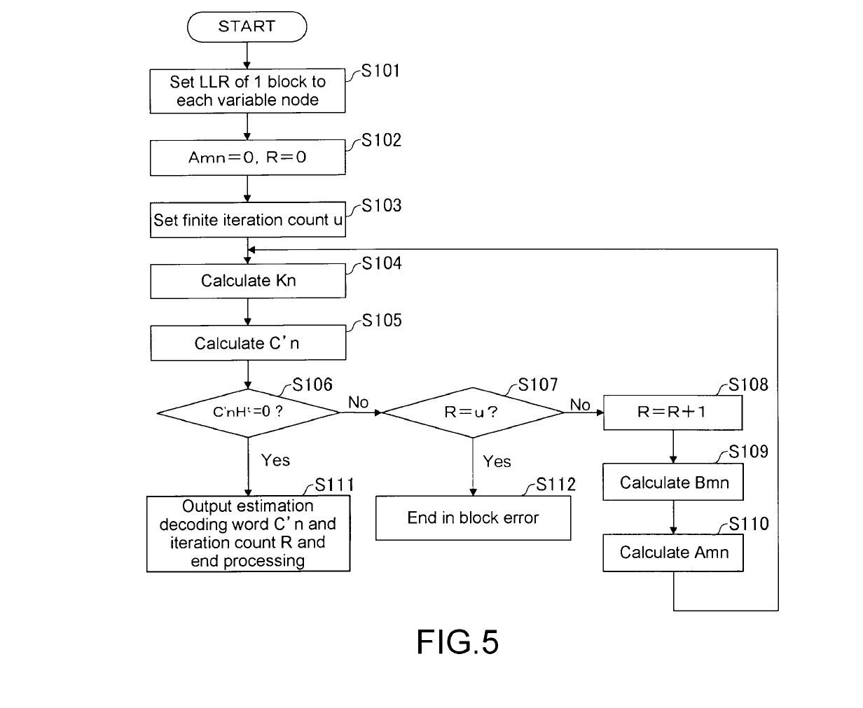

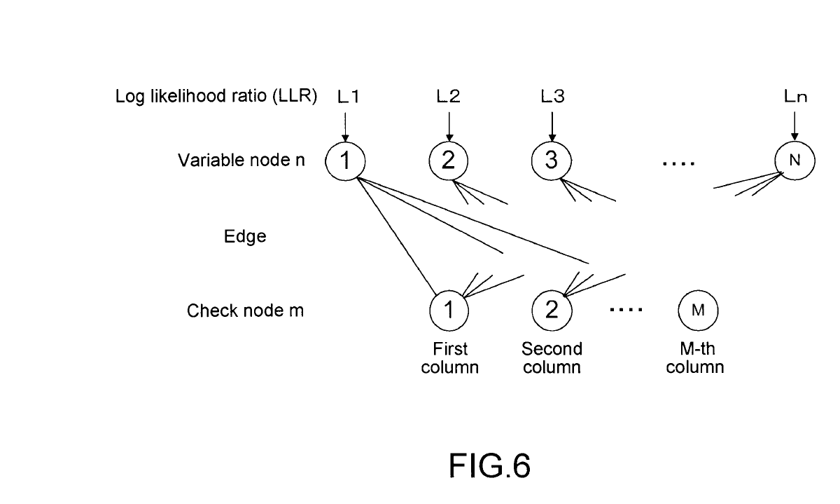

FIG. 5 is a flowchart of the iterative decoding of the LDPC code by the LDPC decoder 32. The LDPC decoder 32 detects the head of the block based on a SYNC detection signal from the SYNC detectors 29A and 29B, and log-likelihood ratios (LLRs) L1, L2, . . . , Ln for each bit of 1 block are sequentially set to the N variable nodes (Step S101) as shown in FIG. 6.

Next, the LDPC decoder 32 initializes a message Amn from a check node to a variable node and an iteration count R (Step S102), and sets the finite iteration count u of the iterative decoding (Step S103).

After that, Steps S104, S105, S106, and S107 are skipped and then the iteration count R is incremented (Step S108). Thereafter, the first iterative processing is performed as follows.

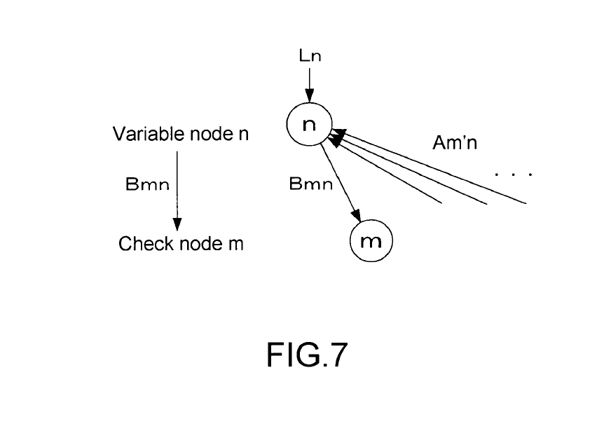

As the variable node processing, the LDPC decoder 32 calculates, from the following expression, a message Bmn given from the variable node n to the check node m (Step S109). FIG. 7 is a diagram showing a method of calculating the message Bmn.

[Expression 1]

$${B}_{mn} = {\sum }_{{n}^{′} ∈ B ( n ) \cdot m} {A}_{mn} + {L}_{n} \qquad ( 1 )$$

Herein, B(n)−m (“−” means “excluding”) is obtained by excluding a check node m from a check node set B(n) linking to a variable node n, which is represented as m′ in FIG. 7. Am′n shown in FIG. 7 is a message to the variable node n calculated with a check node m′. Because an initial value of the message Am′n is 0, the first message Bmn from the variable node n to the check node m is Ln.

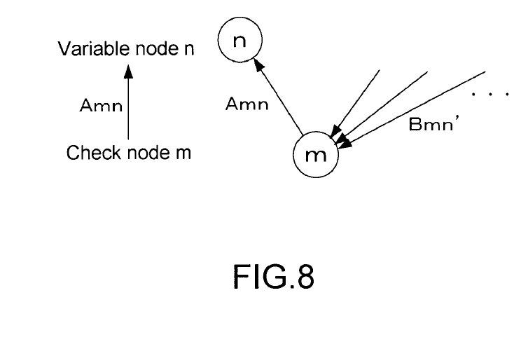

Next, the LDPC decoder 32 calculates a message Amn from the check node m to the variable node n using the following expression (Step S110). FIG. 8 is a diagram showing a calculation method of the message Amn.

[Expression 2]

$${A}_{mn} = {\prod }_{{n}^{′} ∈ A ( m ) \cdot n} sign ( {B}_{mn} ) f ( {\sum }_{{n}^{′} ∈ A ( m ) \cdot n} f ( \vert {B}_{mn} \vert ) ) \qquad ( 2 )$$

Herein, a function f(x) is a Gallager function, and is determined from f(x)=ln((exp(x)+1)/(exp(x)−1)). A(m)−n (“−” means “excluding”) is obtained by excluding the variable node n from a variable node set A(m) linking to the check node m, which is represented as n′. Bmn′ shown in FIG. 8 is a message to the check node m calculated with the variable node n′.

Next, returning to Step S103, the LDPC decoder 32 calculates an approximate value Kn of a log posterior probability ratio using the following expression.

[Expression 3]

$${K}_{n} = {\sum }_{{m}^{′} ∈ B ( n )} {A}_{mn} + {L}_{n} \qquad ( 3 )$$

It is to be noted that for implementation on an LSI, an approximate expression is used for calculating the message Amn, the message Bmn, and the function f(x).

When calculations of the above-mentioned message Amn, message Bmn, approximate value Kn of the log posterior probability ratio are ended, the LDPC decoder 32 determines an estimation decoding word C′n based on the approximate value Kn of the log posterior probability ratio (Step S105). Herein, C′ is a substitute representation of C with circumflex. The determination of the estimation decoding word C′n is performed as follows. When the approximate value Kn of the log posterior probability ratio is equal to or more than 0, the LDPC decoder 32 determines the estimation decoding word C′n to be “0”. When the approximate value Kn of the log posterior probability ratio is less than 0, the LDPC decoder 32 determines the estimation decoding word C′n to be “1”.

Next, the LDPC decoder 32 judges whether the estimation decoding word C′n currently obtained meets a parity check condition of C′nH^{T}=0 (Step S106). Herein, H^{T} is a transposed matrix of the LDPC parity check matrix H. When the estimation decoding word C′n meets the parity check condition, the LDPC decoder 32 outputs the estimation decoding word C′n currently obtained to the data processor 33, outputs the iteration count R at the end of the iterative decoding to the buffer/selector controller 34, and ends the decoding (Step S111).

Herein, a processing starting from the calculations of the message Bmn, the message Amn, the approximate value Kn of the log posterior probability ratio, and the estimation decoding word C′n, to the judgment of whether the estimation decoding word C′n meets the parity check condition is referred to as “one iterative processing”. The number of times the iterative processing is performed is referred to as the iteration count R.

When the result of the judgment in Step S106 shows that the estimation decoding word C′n meets the parity check condition, the LDPC decoder 32 outputs the estimation decoding word C′n currently obtained to the data processor 33 as a decoding result, and ends the iterative decoding. When the estimation decoding word C′n does not meet the parity check condition, a judgment on whether a current iteration count R has reached the finite iteration count u is made (Step S107). When the current iteration count R has not reached the finite iteration count u, the LDPC decoder 32 increments the iteration count R (Step S108), and then carries out the subsequent iterative processing.

In the subsequent processings, the LDPC decoder 32 repeats the iterative processings until it is judged that the estimation decoding word C′n generated meets the parity check condition, or until just before the current iteration count R reaches the finite iteration count u. When it is judged that the current iteration count R has reached the finite iteration count u in Step S107, that is, when the estimation decoding word C′n does not meet the parity check condition even when iterative processings are repeated u times, the LDPC decoder 32 forcibly terminates the decoding processing with a block in processing as an error block (Step S112).

In the magnetic recording/reproducing apparatus according to this embodiment, one LDPC decoder 32 is used in a time-shared manner to perform a time-shared iterative decoding on a plurality of channels.

Next, a description will be given on control to perform the time-shared iterative decoding on the plurality of channels using one LDPC decoder 32 in the time-shared manner. Herein, the number of channels is assumed to be two. In this case, the LDPC decoder 32 is required to be a circuit capable of performing decoding at a rate that is twice or more the channel frequency.

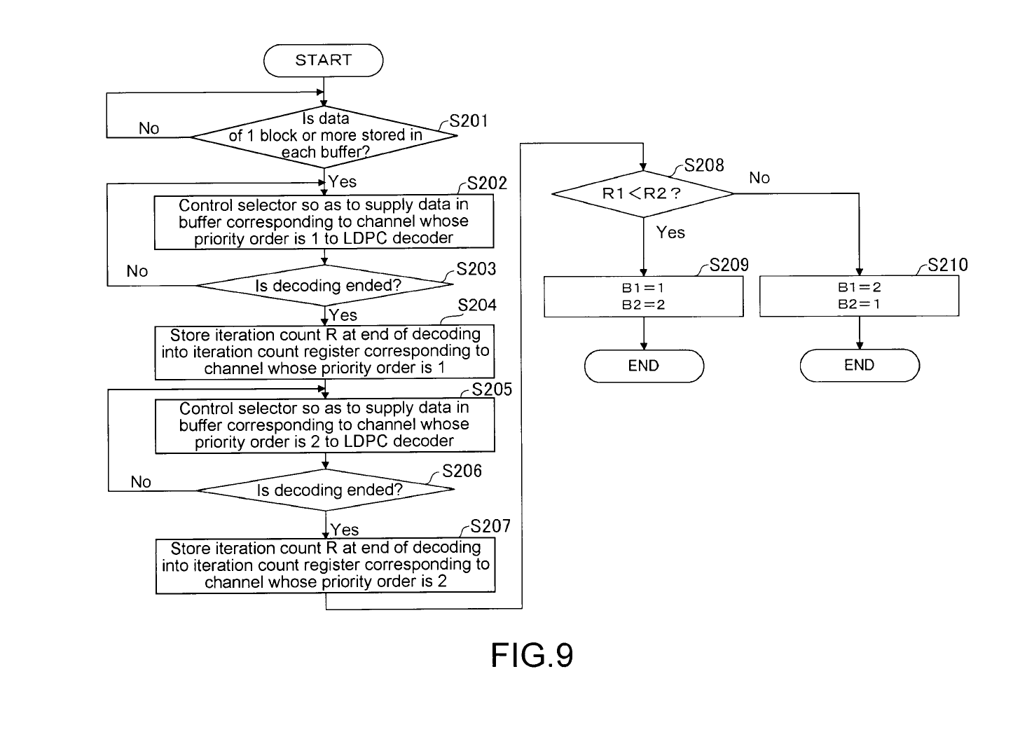

FIG. 9 is a flowchart of control by the buffer/selector controller 34 in the case where the time-shared iterative decoding is performed on two channels using one LDPC decoder 32 in the time-shared manner.

Herein, out of the two channels, one channel is referred to as a “first channel”, while the other channel is referred to as a “second channel”. The buffer/selector controller 34 includes a first priority order register, a second priority register, a first iteration count register, and a second iteration count register. The first priority order register stores a priority order of the iterative decoding on the first channel. The second priority order register stores a priority order of the iterative decoding on the second channel. The first iteration count register stores an iteration count at the end of the latest iterative decoding on the first channel. The second iteration count register stores an iteration count at the end of the latest iterative decoding on the second channel.

First, the buffer/selector controller 34 sets initial values to the priority order registers on the respective channels. For example, a numerical value 1 representing a first-order priority (hereinafter, referred to as “priority order 1”) is set to the first priority order register as the initial value, while a numerical value 2 representing a second-order priority (hereinafter, referred to as “priority order 2”) is set to the second priority order register as the initial value. As a result, at the start of the decoding, the iterative decoding on the first channel is started first, and then the iterative decoding on the second channel is started immediately after the iterative decoding on the first channel is ended.

After that, when detecting that the buffers 30A and 30B on the respective channels are each storing data (LLR) of 1 block or more (Yes in Step S201), the buffer/selector controller 34 outputs a selection signal to the selector 31 so that the data (LLR) in the buffer 30A on the channel set as the priority order 1, that is, the first channel in this case is selected (Step S202). Based on the selection signal from the buffer/selector controller 34, the selector 31 selects the data (LLR) in the buffer 30A on the first channel to supply the data to the LDPC decoder 32. Thus, at the LDPC decoder 32, the iterative decoding with respect to the data (LLR) of 1 block read out from the buffer 30A is carried out by the procedure described above.

For the iterative decoding on the channel selected first out of the plurality of channels, a count U is set to the LDPC decoder 32 as the finite iteration count u. The count U is obtained by dividing, by the total number of channels, the maximum count of iterations that can be performed within a time period required for entirely outputting the data (LLR) of 1 block to each of the buffers 30A and 30B. It is to be noted that the count U is stored in the system in advance. The finite iteration count u may be set upon receiving a notification of the finite iteration count u from the buffer/selector controller 34 by the LDPC decoder 32. Alternatively, when the LDPC decoder 32 receives, from the buffer/selector controller 34, a notification indicating that the decoding is performed on the firstly-selected channel out of the plurality of channels, the count U may be set as the finite iteration count u.

When the LDPC decoder 32 ends the iterative decoding of 1 block (Yes in Step S203), the buffer/selector controller 34 is notified of the iteration count R at the end of the iterative decoding of the block. The buffer/selector controller 34 stores the iteration count R notified from the LDPC decoder 32 in the iteration count register corresponding to the channel to which the priority order 1 has been given, that is, the first iteration count register corresponding to the first channel in this case (Step S204). Herein, the iteration count R stored in the first iteration count register is represented as an “iteration count R1”.

Subsequently, the buffer/selector controller 34 outputs a selection signal to the selector 31 so that the data (LLR) of the buffer 30B on the channel to which the priority order 2 has been given, that is, the second channel in this case is selected (Step S205). Based on the selection signal from the buffer/selector controller 34, the selector 31 selects the data (LLR) of the buffer 30B and supplies the data to the LDPC decoder 32. Thus, at the LDPC decoder 32, the iterative decoding with respect to the data (LLR) of 1 block read out from the buffer 30B is carried out by the procedure described above.

For the iterative decoding on the secondly-selected channel out of the plurality of channels, a count (2U−R) is set to the LDPC decoder 32 as the finite iteration count u. The count (2U−R) is obtained by subtracting the iteration count R at the end of the iterative decoding on the firstly-selected channel from the maximum count (2U in the case where the number of channels is two) of iterations that can be performed within a time period required for entirely outputting the data (LLR) of 1 block to each of the buffers 30A and 30B. The finite iteration count u may be set upon receiving a notification of the finite iteration count u from the buffer/selector controller 34 by the LDPC decoder 32. Alternatively, when the LDPC decoder 32 receives, from the buffer/selector controller 34, a notification indicating that the decoding is performed on the secondly-selected channel, the count 2U−R may be set as the finite iteration count u.

When the LDPC decoder 32 ends the iterative decoding of 1 block (Yes in Step S206), the buffer/selector controller 34 is notified of the iteration count R at the end of the iterative decoding of the block. The buffer/selector controller 34 stores the iteration count R notified from the LDPC decoder 32 in the iteration count register corresponding to the channel to which the priority order 2 has been given, that is, the second iteration count register corresponding to the second channel in this case (Step S207). Herein, the iteration count R stored in the second iteration count register is represented as an “iteration count R2”.

Next, the buffer/selector controller 34 compares the iteration count R1 stored in the first iteration count register with the iteration count R2 stored in the second iteration count register, and judges whether R1<R2 is satisfied (Step S208). In a case where R1<R2 is satisfied, a numerical value 1 is set to the first priority order register as a priority order B1 for the iterative decoding on the first channel, and a numerical value 2 is set to the second priority order register as a priority order B2 for the iterative decoding on the second channel (Step S209). In other words, the priority order registers on the channels still store the initial values. In a case where R1<R2 is not satisfied, conversely, a numerical value 2 is set to the first priority order register as the priority order B1 for the iterative decoding on the first channel, and a numerical value 1 is set to the second priority order register as the priority order B2 for the iterative decoding on the second channel (Step S210).

The control by the buffer/selector controller 34 for an iterative decoding with respect to blocks on two channels at the next time is performed according to the priority orders B1 and B2 set anew to the priority order registers on the channels, respectively. In other words, the next time-shared iterative decoding with respect to the blocks on the plurality of channels is carried out from a channel whose iteration count is smaller at the end of the preceding iterative decoding.

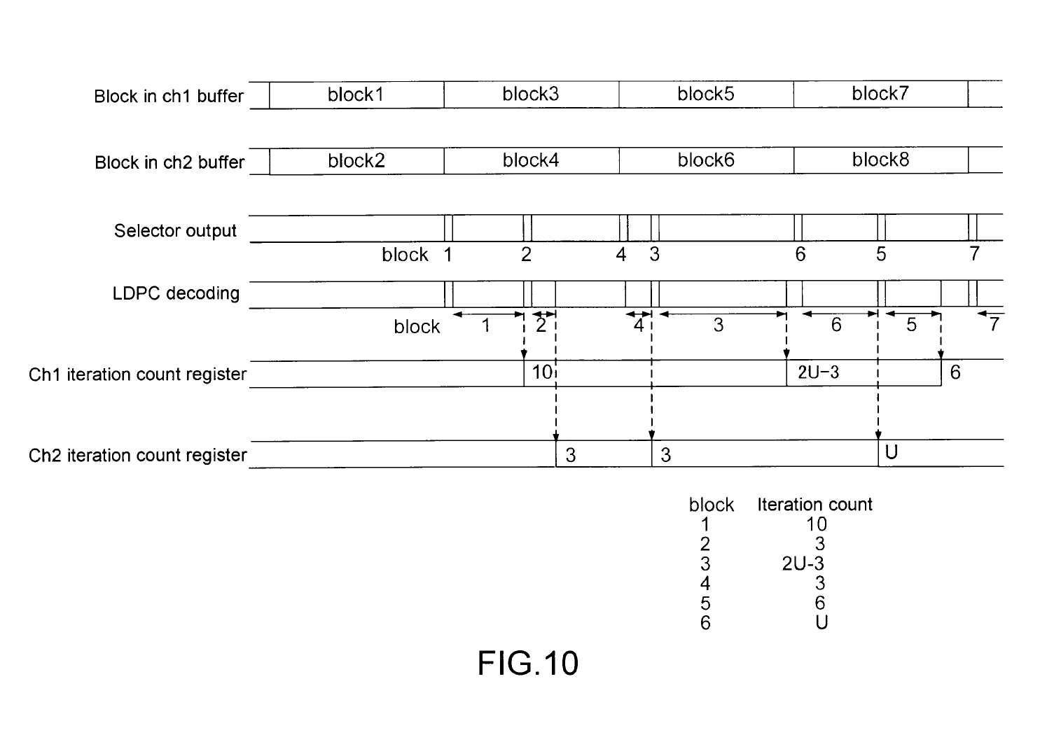

FIG. 10 is a diagram showing an example of a timing chart regarding control on an order of the iterative decoding between the two channels. In this example, the iterative decoding of a block (block 1) stored in the buffer 30A on the first channel (ch 1) is started first. Immediately after the end of the iterative decoding of the block 1, the iterative decoding of a block (block 2) stored in the buffer 30B on the second channel (ch 2) is started. In this case, the iterative processings are performed ten times on the block (block 1) on the first channel (ch 1) and three times on the block (block 2) on the second channel (ch 2), that is, R1=10 and R2=3, which does not satisfy R1<R2. Therefore, the next iterative decoding is started from a block (block 4) stored in the buffer 30B on the second channel (ch 2). Immediately after the end of the iterative decoding of the block (block 4), the iterative decoding of a block (block 3) stored in the buffer 30A on the first channel (ch 1) is performed.

As a result, for the iterative decoding on the two channels in this case, the iterative processing is performed on the block (block 4) three times and on the block (block 3) 2U−3 times. In this way, when a smaller iteration count is required by the end of the iterative decoding on the first channel, a larger iteration count can be assigned to the iterative decoding on the next channel, with the result that a block error occurrence probability can be reduced.

In general, the iteration count at the time of iterative decoding of the LDPC code increases as an SN ratio becomes smaller due to a poor-quality reproduction signal. The quality of the reproduction signal heavily depends on, for example, a characteristic of a recording head or a reproducing head, so the iteration count at the time of the iterative decoding on a specific channel is likely to be larger than that on another channel. Therefore, by performing the iterative decoding first on a channel whose preceding iteration count is smaller, a probability by which a larger finite iteration count u can be assigned to iterative decoding on the next channel is increased.

Heretofore, the case where the number of channels is two is described. Also in a case where the number of channels is three, the iterative decoding is only required to be performed from a channel whose preceding iteration count is smaller among the channels, and thus the present invention can be applied to this case. Of course, in this case, the LDPC decoder 32 must be a circuit capable of performing decoding at a rate of threefold or more the channel frequency.

As described above, according to this embodiment, in the case where the iterative decoding on the plurality of channels is performed using one LDPC decoder 32 in the time-shared manner, by performing such control that the iterative decoding is performed from a channel whose preceding iteration count R is smaller, the larger finite iteration count u can be assigned to the iterative decoding on a channel which tends to require a larger iteration count, with the result that the block error occurrence probability can be reduced.

The present invention is not limited to the above embodiment, and can of course be variously changed without departing from the gist of the present invention.

What is claimed is:

1. A reproduction apparatus configured to reproduce signals of a plurality of channels, comprising:
a soft-decision means for performing a soft decision on each bit of a block for each of the plurality of channels, the block being encoded with an LDPC (low-density parity-check) code as a bit string corresponding to a length of the LDPC code;
a holding means for holding a soft-decision result on a block basis for each of the plurality of channels, the soft-decision result being obtained by the soft-decision means;
a decoding means for inputting the soft-decision result on the block basis and obtaining an estimated bit string by an iterative decoding; and
a control means for determining a priority order among the plurality of channels on each of which a next block is subjected to the iterative decoding, based on an iteration count at an end of the iterative decoding on each of the plurality of channels, and controlling the input of the soft-decision result from the holding means to the decoding means on the block basis for each of the plurality of channels so that the iterative decoding is performed for each of the plurality of channels in accordance with the priority order.

2. The reproduction apparatus according to claim 1,
wherein the soft-decision means obtains a log-likelihood ratio of a posterior probability on a bit basis as the soft-decision result.

3. The reproduction apparatus according to claim 1,
wherein the control means determines the priority order among the plurality of channels so that a next block on a channel on which the iterative decoding is performed a smaller number of times than any other channels at the end of the iterative decoding is subjected to the iterative decoding in priority to the others.

4. The reproduction apparatus according to claim 1,
wherein the decoding means sets an upper limit of the iteration count when the iterative decoding is performed on the plurality of channels.

5. The reproduction apparatus according to claim 1,
wherein the decoding means performs a calculation on a posterior probability in a variable node processing and a check node processing, and performs an iterative processing therebetween.

6. A method of reproducing signals of a plurality of channels, comprising:
performing a soft decision on each bit of a block for each of the plurality of channels, the block being encoded with an LDPC (low-density parity-check) code as a bit string corresponding to a length of the LDPC code;
inputting the soft-decision result on the block basis and obtaining an estimated bit string by an iterative decoding; and
determining a priority order among channels for each of which a next block is subjected to the iterative decoding, based on an iteration count at an end of the iterative decoding for each of the plurality of channels, and performing control so that the iterative decoding is performed for each of the plurality of channels in accordance with the priority order.

7. A reproduction apparatus configured to reproduce signals of a plurality of channels, comprising:
a soft-decision portion for performing a soft decision on each bit of a block for each of the plurality of channels, the block being encoded with an LDPC (low-density parity-check) code as a bit string corresponding to a length of the LDPC code;
a holding portion for holding a soft-decision result on a block basis for each of the plurality of channels, the soft-decision result being obtained by the soft-decision portion;
a decoding portion for inputting the soft-decision result on the block basis and obtaining an estimated bit string by an iterative decoding; and
a control portion for determining a priority order among the plurality of channels on each of which a next block is subjected to the iterative decoding, based on an iteration count at an end of the iterative decoding on each of the plurality of channels, and controlling the input of the soft-decision result from the holding portion to the decoding portion on the block basis for each of the plurality of channels so that the iterative decoding is performed for each of the plurality of channels in accordance with the priority order.
